(19) United States
(12) Patent Application Publication
(10) Pub. No.: US 2013/0083570 A1
(43) Pub. Date: Apr. 4, 2013

(54) SEMICONDUCTOR DEVICE AND METHOD OF MANUFACTURING THE SAME

(71) Applicant: Tadahiro Imada, Kawasaki (JP)

(72) Inventor: Tadahiro Imada, Kawasaki (JP)

(73) Assignee: FUJITSU LIMITED, Kawasaki-shi (JP)

(21) Appl. No.: 13/597,564

(22) Filed: Aug. 29, 2012

(30) Foreign Application Priority Data
Sep. 29, 2011 (JP) 2011-215348

(51) Int. Cl. H01L 29/778; H02M 5/458; H02J 7/00; H01L 21/335

(52) U.S. Cl. 363/37; 257/194; 438/172; 320/107; 257/E29.246; 257/E21.403

(57) ABSTRACT

A semiconductor device includes a first element structure that includes a charge supply layer of first polarity; a charge channel layer of second polarity, the charge channel layer being formed above the charge supply layer and including a recess portion; and a first electrode formed in the recess portion above the charge channel layer.

### CROSS-REFERENCE TO RELATED APPLICATION(S)

This application is based upon and claims the benefit of priority of the prior Japanese Patent Application No. 2011-215348, filed on Sep. 29, 2011, the entire contents of which are incorporated herein by reference.

### FIELD

The embodiments discussed herein are related to semiconductor devices and their manufacturing methods.

### BACKGROUND

Applications of nitride semiconductors to high withstand voltage and high output power semiconductor devices are being studied by taking advantages of their characteristics such as high saturated electron velocities, wide band gaps, etc. For example, GaN is one of the nitride semiconductors, has a band gap of 3.4 eV, which is larger than a band gap of Si (1.1 eV) and a band gap of GaAs (1.4 eV), and a high breakdown electric field intensity. Accordingly, GaN is a promising material for power supply semiconductor devices that operate in high voltages and produce high output powers.

For devices that is made of the nitride semiconductors, there are a number of reports on field-effect transistors, particularly high electron mobility transistors (HEMTs). For example, in GaN HEMTs, AlGaN/GaN HEMTs that use GaN as an electron channel layer and AlGaN as an electron supply layer are drawing attention. In the AlGaN/GaN HEMTs, distortion is produced in AlGaN due to a difference in lattice constant of GaN and AlGaN. The distortion causes spontaneous polarization of AlGaN and piezoelectric polarization, producing highly concentrated two dimensional electron gas (2DEG). Thus, it is expected that the devices using the nitride semiconductors may be utilized as high efficiency switching elements and high withstand power devices for electric vehicles, etc.
[Patent document] Japanese Laid-open Patent Publication No. 2007-220895

At present, GaN nitride semiconductors are not put into practical use as p-type transistors. It is because only n-type transistors may be operable in RF applications which are already put into practical use, and n-type HEMTs may operate at much higher speeds than p-type HEMTs.

On the other hand, when GaN nitride semiconductors are used for power supply devices, it is desirable to have a faster rise in electric current at turning ON.

The slower the current rise becomes, the longer the electric current has to flow through a high resistance, resulting in higher electric power consumption.

It is considered that p-type GaN transistors may achieve a faster rise in electric current than n-type GaN transistors. In light of the above, although a n-type transistor may be used as a transistor that operates as a power supply device, it is desirable to use a p-type transistor in its driver's high-side.

### SUMMARY

According to an aspect of the invention, a semiconductor device includes a first element structure that includes a charge supply layer of first polarity; a charge channel layer of second polarity, the charge channel layer being formed above the charge supply layer and including a recess portion; and a first electrode formed in the recess portion above the charge channel layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A-1C are schematic cross-sectional views illustrating a manufacturing method of a p-type GaN transistor according to a first embodiment in order of process;

FIGS. 2A and 2B are schematic cross-sectional views, which follow FIGS. 1A-1C, illustrating the manufacturing method of a p-type GaN transistor according to the first embodiment in order of process;

FIGS. 3A and 38 are schematic cross-sectional views, which follow FIGS. 2A and 2B, illustrating the manufacturing method of a p-type GaN transistor according to the first embodiment in order of process;

FIG. 4 is a schematic plane view illustrating a structure of a p-type GaN transistor according to the first embodiment;

FIG. 5 is a connection wiring diagram illustrating a battery charger according to a second embodiment;

FIGS. 6A-6C are schematic cross-sectional views illustrating key steps of a manufacturing method of an AlGaN/GaN HEMT including a gate driver circuit according to a third embodiment;

FIGS. 7A and 7B are schematic cross-sectional views, which follow FIGS. 6A-6C, illustrating key steps of the manufacturing method of an AlGaN/GaN HEMT including a gate driver circuit according to the third embodiment;

FIGS. 8A and 8B are schematic cross-sectional views, which follow FIGS. 7A and 7B, illustrating key steps of the manufacturing method of an AlGaN/GaN HEMT including a gate driver circuit according to the third embodiment;

FIG. 9 is a schematic plane view of an AlGaN/GaN HEMT including a gate driver circuit according to the third embodiment;

FIG. 10 is a characteristic diagram illustrating measurement results regarding a relation between a drain-source voltage Vds and a drain current Id;

FIG. 11 is a characteristic diagram illustrating measurement results regarding a relation between a drain voltage Vd and time t;

FIG. 12 is a schematic plane view illustrating a HEMT chip structure;

FIG. 13 is a schematic plane view illustrating a discrete package;

FIG. 14 is a connection wiring diagram illustrating a PFC circuit according to a fourth embodiment;

FIG. 15 is a connection wiring diagram illustrating a schematic structure of a power supply apparatus according to a fifth embodiment; and

FIG. 16 is a connection wiring diagram illustrating a schematic structure of a high frequency amplifier according to a sixth embodiment.

### DESCRIPTION OF EMBODIMENTS

Hereinafter, embodiments will be described in detail with reference to the drawings. In the following embodiments, structures of compound semiconductor devices and their manufacturing methods are described. Note that, in the following drawings, relative sizes and thicknesses of some of constituting members are not precisely illustrated for the sake of illustration.

### First Embodiment

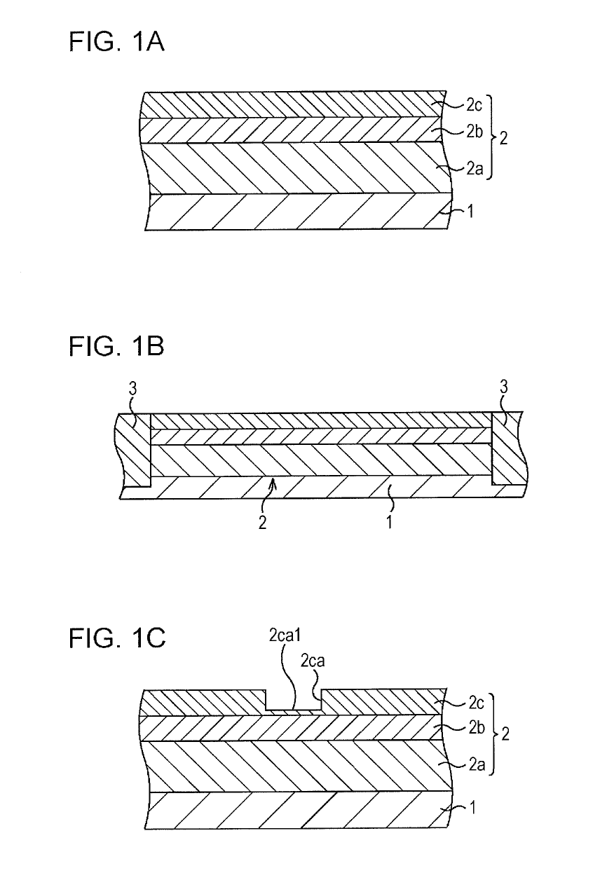

The present embodiment discloses a p-type GaN semiconductor of metal insulator semiconductor (MIS) type as the compound semiconductor device. FIGS. 1A-1C, 2A-2B, and 3A-3B are schematic cross-sectional views collectively illustrating a manufacturing method of the p-type GaN transistor according to the first embodiment in order of process.

First, as illustrated in FIG. 1A, a compound semiconductor multilayer structure 2 is formed on a growth substrate such as a Si substrate 1, for example. Alternatively, instead of the Si substrate, a sapphire substrate, a GaAs substrate, a SIC substrate, a GaN substrate, or the like may be used as the growth substrate. With regard to the substrate conductivity, both semi-insulating and conductive substrates may be used.

The compound semiconductor multilayer structure 2 is configured to include a buffer layer 2a, a hole supply layer 2b, and a hole channel layer 2c. The hole channel layer 2c has p-type conductivity, and has positive polarity that produces a two dimensional hole gas at an interface with the hole supply layer 2b, as will be described below. On the other hand, the hole supply layer 2b has negative polarity.

More specifically, the following compound semiconductors are each grown on the Si substrate 1 by a metal organic vapor phase epitaxy (MOVPE) method, for example. Alternatively, instead of the MOVPE method, a molecular beam epitaxy (MBE) method or the like may be used. The compound semiconductors that become the buffer layer 2a, the hole supply layer 2b, and the hole channel layer 2c are sequentially grown on the Si substrate 1. The buffer layer 2a is formed on the Si substrate 1 by growing AlN to a thickness of about 0.1 μm. The hole supply layer 2b is formed by growing n-AlGaN to a thickness of about 30 nm. The hole supply layer 2b may alternatively be formed as an intentionally undoped AlGaN (i-AlGaN).

The hole channel layer 2c is formed by growing p-GaN to a thickness of about 1-1000 nm, for example. When the thickness is less than 1 nm, a transistor operation becomes unstable. When the thickness is larger than 1000 nm, a process control becomes difficult. Accordingly, the present embodiment may be reliably enabled by forming the hole channel layer 2c with the thickness of about 1-1000 nm. In the present embodiment, p-GaN of the hole channel layer 2c is formed to a thickness of about 200 nm.

A mixture of ammonia (NH₃) gas and trimethylgallium (TMGa) gas, which is a source of Ga, is used as a source gas for the growth of GaN. For the growth of AlGaN, a mixture of TMAI gas, TMGa gas, and NH₃ gas is used as a source gas. The supplies and the flow rates of TMAI gas and TMGa are arbitrarily determined according to the compound semiconductor layer to be grown. The flow rate of NH₃ that is the common source gas is about 100 sccm-10 slm. Furthermore, the growth pressure is about 50-300 Torr, and the growth temperature is about 1000-1200° C.

When AlGaN is being grown as n-type—namely when the hole supply layer 2b (n-AlGaN) is being formed—, a n-type dopant is added to the source gas of AlGaN. In the present embodiment, AlGaN is doped with, for example, Si by adding, for example, silane (SiH₄) gas which includes Si to the source gas at a predetermined flow rate. The Si doping concentration is about 1×10¹⁸-1×10²⁰/cm³, or about 2×10¹⁸/cm³, for example.

When GaN is being grown as p-type—namely when the hole channel layer 2c (p-GaN) is being formed—, a p-type dopant is added to the source gas of GaN. The p-type dopant may be one selected from the group consisting Mg and C, for example. In the present embodiment, Mg is used as the p-type dopant. GaN is doped with Mg by adding Mg to the source gas at a predetermined flow rate. The Mg doping concentration is about 1×10¹⁶-1×10²¹/cm³, for example. When the doping concentration is lower than about 1×10¹⁶/cm³, the transistor does not operate as p-type. When the doping concentration is higher than about 1×10²¹/cm³, crystalline property may be exacerbated, causing a leak current increase, etc. Accordingly, the present embodiment may be reliably enabled by setting the Mg doping concentration to about 1×10¹⁶-1×10²¹/cm³. In the present embodiment, the Mg doping concentration of the hole channel layer 2c is about 1×10¹⁹/cm₃.

In the compound semiconductor multilayer structure 2 thus formed, piezoelectric polarization is induced in the hole channel layer 2c of positive polarity at an interface with the hole supply layer 2b by strain due to a difference in lattice constant of GaN and AlGaN. This piezoelectric polarization effect together with effects of spontaneous polarization of the hole supply layer 2b and the hole channel layer 2c, produces a two dimensional hole gas (2DHG) with a high hole concentration at the GaN/AlGaN interface.

After forming the compound semiconductor multilayer structure 2, the hole channel layer 2c is annealed at about 700° C. for about 30 minutes.

As illustrated in FIG. 18, isolation structures 3 are formed. In FIG. 1C and beyond, the isolation structures 3 will not be illustrated. More specifically, argon (Ar) ions, for example, are implanted into isolation regions of the compound semiconductor multilayer structure 2. Thus, the isolation structures 3 are formed in surface portions of the compound semiconductor multilayer structure 2 and the Si substrate 1. The isolation structures 3 define active regions on the compound semiconductor multilayer structure 2. Instead of the above implantation method, the isolation process may alternatively be performed by employing another well-known method such as a shallow trench isolation (STI) process, etc. In this case, chlorine etching gas, for example, is used for dry etching the compound semiconductor multilayer structure 2.

Subsequently, as illustrated in FIG. 1C, an electrode recess 2ca is formed in the hole channel layer 2c. More specifically, the hole channel layer 2c is coated with resist and then processed by photolithography. Thus, a resist mask 10A with an opening 10Aa is formed. The opening 10Aa exposes a predetermined portion of the hole channel layer 2c, or in this case a portion at which a gate electrode is to be formed.

Next, the hole channel layer 2c is processed by dry etching with the resist mask 10A. Thus, the electrode recess 2ca is formed in the hole channel layer 2c at a position where the gate electrode is to be formed. A portion of p-GaN may remain in a non-penetrating recessed portion of the electrode recess 2ca—namely in a bottom surface of the electrode recess 2ca. When such a portion of p-GaN remains, a bottom portion 2ca1 thus remained becomes a current path below the gate electrode. The bottom portion 2ca1 may have a thickness of about 1-100 nm. When the thickness is less than 1 nm, a transistor operation becomes unstable. When the thickness is larger than 100 nm, a transistor becomes normally-on. Accordingly, a normally-off p-type transistor may be formed by having a thickness of about 1-100 nm. In the present embodiment, the thickness of the bottom portion 2ca1 of the electrode recess 2ca is about 5 nm. The resist mask 10A is removed by an ashing process or a wet process using predetermined chemical solutions.

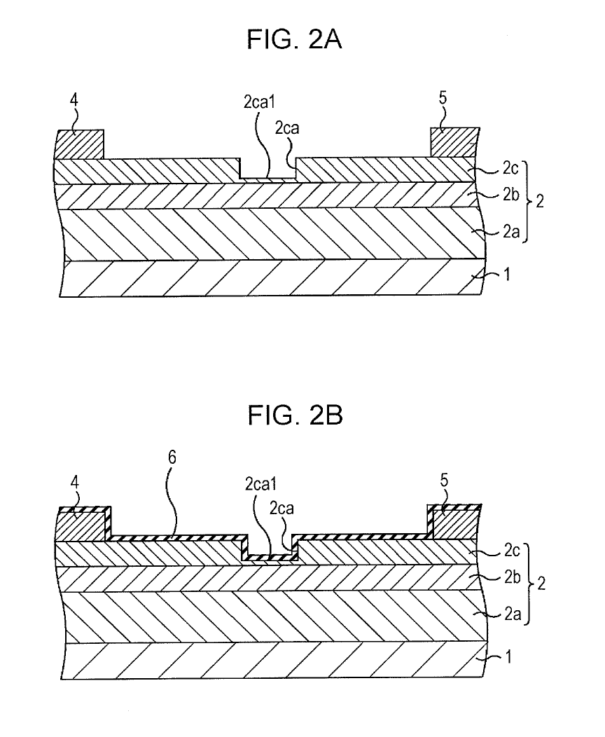

Next, as illustrated in FIG. 2A, a source electrode 4 and a drain electrode 5 are formed. More specifically, first, a resist mask is formed for forming the source electrode 4 and the drain electrode 5. Here, a resist mask suitable for an evaporation method and a lift-off method such as a double layer resist of undercut profile is used, for example. The compound semiconductor multilayer structure 2 is coated with this resist, and openings are formed on the surface of the hole channel layer 2c to expose positions at which the source electrode and the drain electrode are to be formed. Thus, the resist mask having such openings is formed.

With using this resist mask, an electrode material such as Ni, for example, is deposited on the resist mask having the openings by an evaporation method, for example. Ni is deposited to a thickness of about 100 nm. The resist mask and Ni deposited thereon are removed by a lift-off method. Subsequently, the Si substrate 1 is subjected to a heat treatment at 400-1000° C., or more specifically about 600 for example, in nitrogen atmosphere, for example, to form ohmic contacts between remaining Ni and p-GaN of the hole channel layer 2c. In some cases, no heat treatment may be performed if the ohmic contacts between Ni and the hole channel layer 2c are formed without any treatment. Thus, the source electrode 4 and the drain electrode 5 are formed.

Next, as illustrated by FIG. 2B, a gate insulation film 6 is formed. More specifically, an insulation material such as Al₂O₃, for example, is deposited on the compound semiconductor multilayer structure 2 so as to cover inner walls of the electrode recess 2ca. Al₂O₃ is formed by an atomic layer deposition (ALD) method, for example, in which TMA gas and O₃ are alternately supplied. In the present embodiment, Al₂O₃ is deposited to a thickness of 2-200 nm, or more specifically 10 nm, for example, in this case. Thus, the gate insulation film 6 is formed.

Instead of the ALD method, Al₂O₃ may be deposited by a plasma CVD method, a sputtering method, etc. Furthermore, instead of depositing Al₂O₃, nitride or oxynitride of Al may be deposited. Alternatively, the gate insulation film may be formed by depositing oxide, nitride, oxynitride of one element selected from the group consisting of Si, Hf, Zr, Ti, Ta, and W, or by depositing multiple layers of suitably selected members thereof.

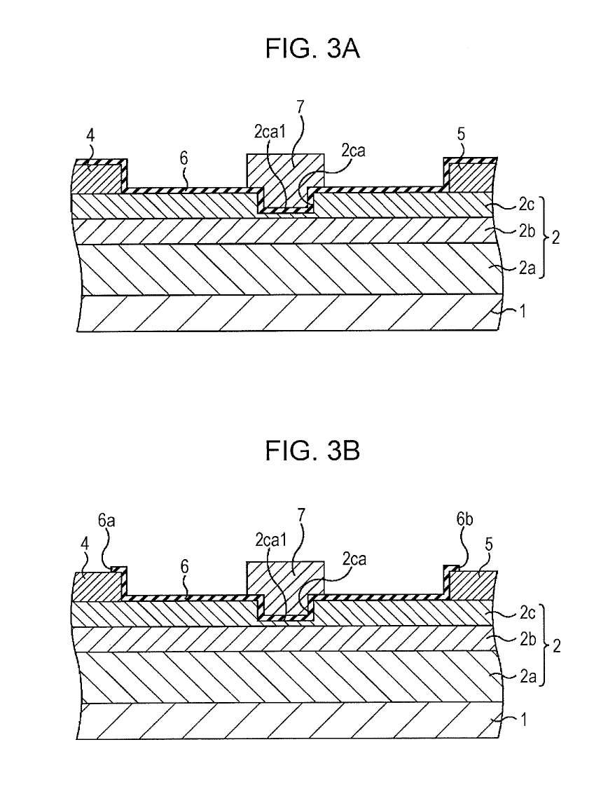

Subsequently, as illustrated by FIG. 3A, a gate electrode 7 is formed. More specifically, first, a resist mask is formed on the gate insulation film 6 for forming the gate electrode 7. The gate insulation film 6 is coated with resist, and an opening is formed to expose a portion at the surface of the gate insulation film 6. The portion is aligned with the electrode recess 2ca positioned below. Thus, the resist mask having such an opening is formed.

With using this resist mask, an electrode material such as Ti, for example, is deposited on the resist mask having the foregoing opening by an evaporation method, for example. Ti is deposited to a thickness of about 100 nm. The resist mask and Ti deposited thereon are removed by a lift-off method. Thus, the gate electrode 7 is formed in such a way that its lower portion is buried into the electrode recess 2ca of the hole channel layer 2c with having the gate insulation film 6 in between while its upper portion protrudes upward from the electrode recess 2ca with having the gate insulation film 6 in between.

Subsequently, as illustrated in FIG. 3B, openings 6a and 6b are formed in the insulation film 6 at positions above the source electrode 4 and the drain electrode 5. More specifically, the gate insulation film 6 is processed by photolithography and dry etching, and portions of the gate insulation film 6 at the positions above the source electrode 4 and the drain electrode 5 are removed. Thus, the openings 6a and 6b, which expose surfaces of the source electrode 4 and the drain electrode 5, are formed in the gate insulation film 6.

Subsequently, a plurality of process steps are performed to complete the p-type GaN transistor of MIS type according to the present embodiment. The process steps may include steps such as electrical connections of the source electrode 4, the drain electrode 5, and the gate electrode 7; pad formation of the source electrode 4, the drain electrode 5, and the gate electrode 7; etc.

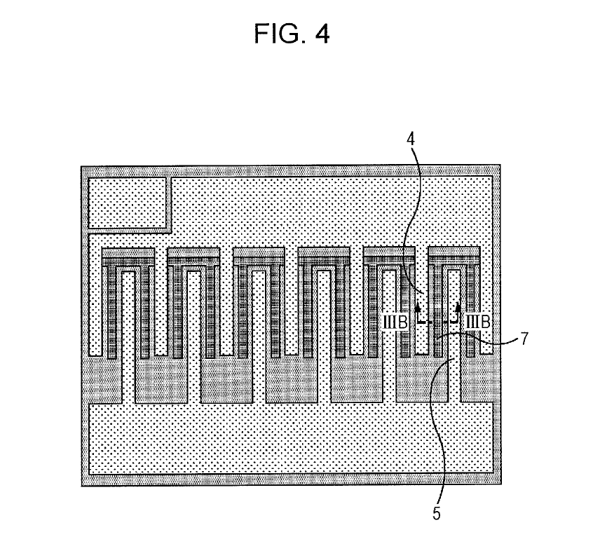

FIG. 4 illustrates a plane view of the p-type GaN transistor according to the present embodiment. FIG. 3B corresponds to a cross-section along a dashed line IIIB-IIIB of FIG. 4. As illustrated in the figure, the source electrode 4 and the drain electrode 5 are formed in comb teeth like shapes and arranged in parallel to each other. The gate electrode 7 is also formed in a comb teeth like shape, and is arranged in between and in parallel to the source electrode 4 and the drain electrode 5.

The present embodiment is described using the p-type GaN transistor of MIS type, in which the gate electrode is formed on the compound semiconductor (p-GaN) with having the gate insulation film in between, as an example. However, the present embodiment is not limited to that example. Alternatively, instead of the MIS type, the present embodiment may also be applicable to a p-type GaN transistor of Schottky type in which the gate electrode is formed directly on the compound semiconductor (p-GaN).

As described above, according to the present embodiment, a highly reliable p-type GaN transistor that has a rapid current rise at turning ON is realized.

### Second Embodiment

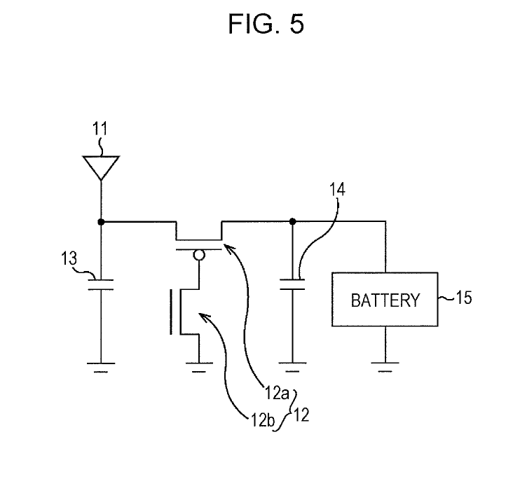

The present embodiment discloses a battery charger including a p-type GaN transistor according to the first embodiment. FIG. 5 is a connection wiring diagram illustrating the battery charger according to the second embodiment.

The battery charger includes a power supply circuit 11 for supplying a power source voltage, and is configured such that a transistor 12 and capacitors 13, 14 are connected in parallel. The transistor 12 and the capacitors 13, 14 are grounded at one ends. The transistor 12 is configured to include a p-type GaN transistor 12a according to the first embodiment and a n-type transistor 12b. A battery 15 is connected to the battery charger with its one end being grounded for charging.

The present embodiment employs the p-type GaN transistor according to the first embodiment in the battery charger. Thus, a highly reliable battery charger is realized.

### Third Embodiment

The present embodiment discloses an AlGaN/GaN HEMT including a gate driver circuit as the compound semiconductor device. In the present embodiment, the AlGaN/GaN HEMT, in which the gate driver circuit for driving its gate electrode is formed on the same substrate, is described as an example. Here, a p-type GaN transistor is employed in the gate driver circuits high side. In the low side of the gate driver circuit, a n-type AlGaN/GaN HEMT similar to the one described above may be formed, for example, although a description thereof is omitted.

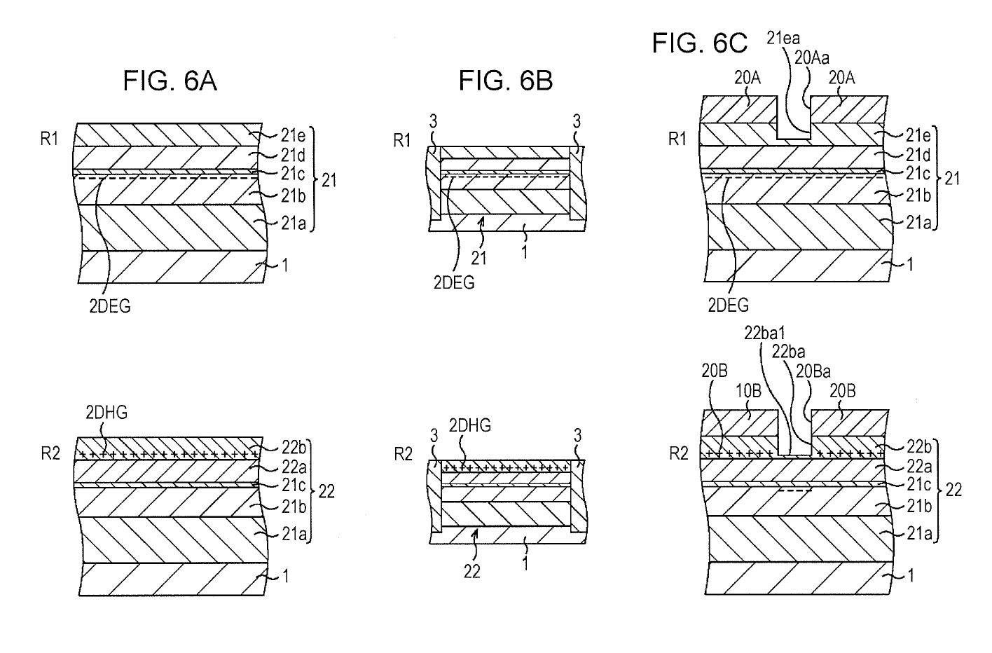

FIGS. 6A-6C, 7A-7B, and 8A-8B are schematic cross-sectional views illustrating a manufacturing method of the AlGaN/GaN HEMT according to the third embodiment in order of process. In each of the figures, the upper half indicates a formation region R1 for the AlGaN/GaN HEMT, and the lower half indicates a formation region R2 for the p-type GaN transistor employed in the gate driver circuit's high side. In the formation regions R1 and R2, the same reference numerals denote the common constituting members.

To separately form constituting members in the formation regions R1 and R2, the following techniques may be used, for example. One of the formation regions R1 and R2, in which constituting members are not formed, is coated with a resist mask, and then films of the constituting members are deposited across the formation regions R1 and R2. After completing the formation of the constituting members, the films of the constituting members, which will not be used, are peeled and removed together with the resist mask. Alternatively, first, films of constituting members may be deposited on the formation regions R1 and R2. Subsequently, the films of constituting members, which will not be used, may be removed by lithography or dry etching during the formation of the constituting members or after the formation of the constituting members.

First, as illustrated in FIG. 6A, compound semiconductor multilayer structures 21 and 22 are formed on a growth substrate such as a Si substrate 1, for example. Alternatively, instead of the Si substrate, a sapphire substrate, a GaAs substrate, a SiC substrate, a GaN substrate, or the like may be used as the growth substrate. With regard to the substrate conductivity, both semi-insulating and conductive substrates may be used.

The compound semiconductor multilayer structure 21 is configured to include a buffer layer 21a, an electron channel layer 21b, an intermediate layer (spacer layer) 21c, an electron supply layer 21d, and a cap layer 21e. The electron channel layer 21b produces a two dimensional electron gas at an interface with the intermediate layer 21c, as will be described below. The electron supply layer 21d is n-type. Both the electron channel layer 21b and the electron supply layer 21d have negative polarity.

The compound semiconductor multilayer structure 22 is configured to include the buffer layer 21a, the electron channel layer 21b, the intermediate layer (spacer layer) 21c, a hole supply layer 22a that is the same layer as the electron supply layer 21d, and a hole channel layer 22b. The hole channel layer 22b has p-type conductivity, and has positive polarity that produces a two dimensional hole gas at an interface with the hole supply layer 22a, as will be described below. On the other hand, the hole supply layer 22a has negative polarity.

More specifically, the following compound semiconductors are each crown on the Si substrate 1 by a MOVPE method, for example. Alternatively, instead of the MOVPE method, a molecular beam epitaxy (MBE) method or the like may be used. The compound semiconductors that become the buffer layer 21a, the electron channel layer 21b, the intermediate 21c, and the electron supply layer 21d (hole supply layer 22a) are sequentially grown on the Si substrate 1 in the formation regions R1 and R2. Subsequently, the compound semiconductor that becomes the cap layer 21e is grown on the electron supply layer 21d in the formation region R1, and the compound semiconductor that becomes the hole channel layer 22b is grown on the hole supply layer 22a in the formation region R2.

The buffer layer 21a is formed on the Si substrate 1 by growing AlN to a thickness of about 0.1 μm. The electron channel layer 21b is formed by growing i-GaN to a thickness of about 1-3 μm. The intermediate layer 21c is formed by growing i-AlGaN to a thickness of about 5 nm. The electron supply layer 21d (hole supply layer 22a) is formed by growing n-AlGaN to a thickness of about 30 nm. The intermediate layer 21c is not formed in some cases. The electron supply layer 21d (hole supply layer 22a) may alternatively be formed as i-AlGaN.

The cap layer 21e is formed by growing n-GaN to a thickness of about 10 nm. The hole channel layer 22b is formed by growing p-GaN to a thickness of about 1-1000 nm, for example. When the thickness is less than 1 nm, a transistor operation becomes unstable. When the thickness is larger than 1000 nm, a process control becomes difficult. Accordingly, the present embodiment may be reliably enabled by forming the hole channel layer 22b with a thickness of about 1000 nm. In the present embodiment, p-GaN of the hole channel layer 22b is formed to a thickness of about 200 nm.

A mixture of ammonia (NH₃) gas and trimethylgallium (TMGa) gas, which is a source of Ga, is used as a source gas for the growth of GaN. For the growth of AlGaN, a mixture of TMAI gas, TMGa gas, and NH₃ gas is used as a source gas. The supplies and the flow rates of TMAI gas and TMGa are arbitrarily determined according to the compound semiconductor layer to be grown. The flow rate of NH₃ gas that is the common source is about 100 sccm-10 slm. Furthermore, the growth pressure is about 50-300 Torr, and the growth temperature is about 1000-1200° C.

When AlGaN and GaN are being grown as n-type—namely when the electron supply layer 21d (hole supply layer 22a) (n-AlGaN) and the cap layer 21e are being formed—, a n-type dopant is added to the source gases of AlGaN and GaN, respectively. In the present embodiment, AlGaN and GaN are doped with, for example, Si by adding, for example, silane (SiH₄) gas which includes Si to the respective source gases at predetermined flow rates. The Si doping concentration is about 1×10¹⁸-1×10²⁰/cm³, or about 2×10¹⁸/cm³, for example.

When GaN is being grown as p-type—namely when the hole channel layer 22b (p-GaN) is being formed—, a p-type dopant is added to the source gas of GaN. The p-type dopant may be one selected from the group consisting Mg and C, for example. In the present embodiment, Mg is used as the p-type dopant. GaN is doped with Mg by adding Mg to the source gas at a predetermined flow rate. The Mg doping concentration is about 1×10¹⁶-1×10²¹/cm³, for example. When the doping concentration is lower than about 1×10¹⁶/cm³, the transistor does not operate as the p-type. When the doping concentration is higher than about 1×10²¹/cm³, crystalline property may be exacerbated, causing a leak current increase, etc. Accordingly, the present embodiment may be reliably enabled by setting the Mg doping concentration to about 1×10¹⁶-1×10²¹/cm³. In the present embodiment, the Mg doping concentration of the hole channel layer 22b is about 1×10¹⁹/cm³.

In the compound semiconductor multilayer structure 21 thus formed, piezoelectric polarization is induced in the electron channel layer 21b of negative polarity at an interface with the electron supply layer 21d (more precisely, an interface with the intermediate layer 21c. Hereinafter, referred to as GaN/AlGaN interface) by strain due to a difference in lattice constant of GaN and AlGaN. This piezoelectric polarization effect, together with effects of spontaneous polarization of the electron channel layer 21b and the electron supply layer 21d, produces a two dimensional electron gas (2DEG) with a high electron concentration at the GaN/AlGaM interface.

In the compound semiconductor multilayer structure 22 thus formed, piezoelectric polarization is induced in the hole channel layer 22b of positive polarity at an interface with the hole supply layer 22a by strain due to a difference in lattice constant of GaN and AlGaN. This piezoelectric polarization effect, together with effects of spontaneous polarization of the hole supply layer 22a and the hole channel layer 22b, produces the 2DHG with a high hole concentration at the GaN/AlGaN interface.

After forming the compound semiconductor multilayer structure 22, the hole channel layer 22b is annealed at about 700° C. for about 30 minutes.

As illustrated by FIG. 6B, an isolation structure 3 is formed. In FIG. 6C and beyond, the isolation structures 3 will not be illustrated. More specifically, for example, argon (Ar) ions are implanted into isolation regions of the compound semiconductor multilayer structures 21 and 22. Thus, the isolation structures 3 are formed in surface portions of the compound semiconductor multilayer structures 21, 22 and the Si substrate 1. The isolation structures 3 define active regions on the compound semiconductor multilayer structures 21 and 22. Instead of the above implantation method, the isolation process may alternatively be performed by employing another well-known method such as a shallow trench isolation (STI) process, etc. In this case, chlorine etching gas, for example, is used for dry etching the compound semiconductor multilayer structures 21 and 22.

Next, as illustrated in FIG. 6C, an electrode recess 21ea is formed in the cap layer 21e in the formation region R1, and an electrode recess 22ba is formed in the hole channel layer 22b in the formation region R2.

First, the formation of the electrode recess 21ea is described. The formation regions R1 and R2 are coated with resist and then processed by photolithography. Thus, a resist mask 20A with an opening 20Aa is formed. The opening 20Aa exposes a portion of the cap layer 21e, which corresponds to a position where a gate electrode is to be formed in the formation region R1. Next, the cap layer 21e is processed by dry etching with the resist mask 20A. Thus, the electrode recess 21ea is formed with having a predetermined depth in the cap layer 21e at a position where the gate electrode is to be formed. The resist mask 20A is removed by an asking process or a wet process using predetermined chemical solutions.

Next, the formation of the electrode recess 22ba is described. The formation regions R1 and R2 are coated with resist and then processed by photolithography. Thus, a resist mask 20B with an opening 20Ba is formed. The opening 20Ba exposes a portion of the hole channel layer 22b, which corresponds to a position where a gate electrode is to be formed in the formation region R2.

Next, the hole channel layer 22b is processed by dry etching with the resist mask 20B, Thus, the electrode recess 22ba is formed in the hole channel layer 22b at a position where the gate electrode is to be formed. A portion of p-GaN may remain at a non-penetrating recessed portion of the electrode recess 22ba—namely in a bottom surface of the electrode recess 22ba. When such a portion of p-GaN remain, a bottom portion 22ba1 this remained becomes a current path below the gate electrode. The bottom portion 22ba1 has a thickness of about 1-100 nm. When the thickness is less than 1 nm, a transistor operation becomes unstable. When the thickness is larger than 100 nm, a transistor becomes normally-on. Accordingly, a normally-off p-type transistor may be formed by having a thickness of about 1-100 nm. In the present embodiment, the thickness of the bottom portion 22ba1 of the electrode recess 22ba is about 5 nm. The resist mask 209 is removed by an ashing process or a wet process using predetermined chemical solutions.

Even in the compound semiconductor multilayer structure 22, 2DEG is produced in the electron channel layer 21b at an interface with the hole supply layer 22a (more precisely, an interface with the intermediate layer 21c) due to the formation of the electrode recess 22ba. The 2DEG is formed only at a portion of the electron channel layer 21b, which aligned with the electrode recess 22ba positioned above. In the present embodiment, the use of the 2DEG in the compound semiconductor multilayer structure 22 is not explicitly specified, and the 2DEG may be used for a predetermined application.

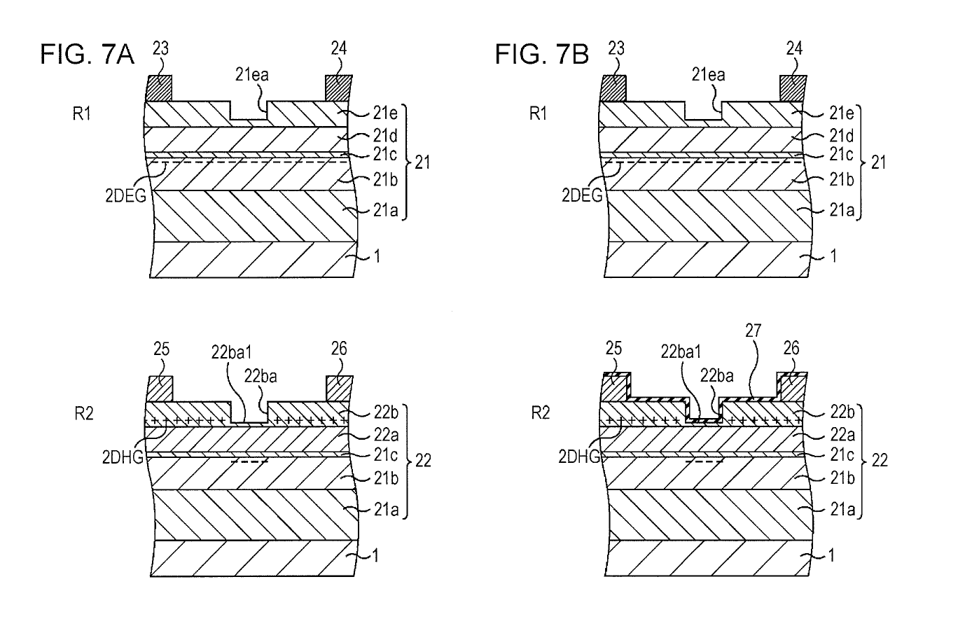

Next, as illustrated in FIG. 7A, a source electrode 23 and a drain electrode 24 are formed in the formation region R1, and a source electrode 25 and a drain electrode 26 are formed in the formation region R2.

First, the formation of the source electrode 23 and the drain electrode 24 are described. Electrode recesses 21eb and 22ec are formed in the surface of the compound semiconductor multilayer structure 21 at positions (electrode forming positions) where the source electrode 23 and the drain electrode 24 are to be formed. The surface of the compound semiconductor multilayer structure 21 is coated with resist. The resist is processed by photolithography, and openings are formed in the resist at positions corresponding to the electrode forming positions for exposing the surface of the compound semiconductor multilayer structure 21. Thus, a resist mask having such openings is formed.

With using the resist mask, dry etching is performed to remove part of the cap layer 21e until the surface of the electron supply layer 21d is exposed at the electrode forming positions. Thus, the electrode recesses 21eb and 22ec are formed such that the surface of the electron supply layer 21d is exposed at the electrode forming positions. As to etching conditions, the etching gas includes inert gas such as Ar, etc. and chlorine gas such as Cl₂, etc. with a Cl₂ flow rate of 30 sccm, a Cl₂ pressure of 2 Pa, and an RF input power of 20 W, for example. Alternatively, the electrode recesses 21eb and 22ec may be formed by etching the cap layer 21e into an intermediate position thereof or by etching through beyond the electron supply layer 21d. The resist mask is removed by an ashing process, etc.

A resist mask is formed on the formation region R1 for forming the source electrode 23 and the drain electrode 24. Here, a resist mask suitable for an evaporation method and a lift-off method such as a double layer resist of undercut profile is used, for example. The formation regions R1 and R2 are coated with this resist, and openings are formed for exposing the electrode recesses 21eb and 22ec of the electron supply layer 21d of the compound semiconductor multilayer structure 21 in the formation region R1. Thus, the resist mask having such openings is formed.

With using this resist mask, electrode materials such as Ta/Al, for example, are deposited on the resist mask having the openings by an evaporation method, for example. Ta has a thickness of about 20 nm, and Al has a thickness of about 200 nm. The resist mask and Ta/Al deposited thereon are removed by a lift-off method.

Next, the formation of the source electrode 25 and the drain electrode 26 are described. A resist mask is formed on the formation region R2 for forming the source electrode 25 and the drain electrode 26. Here, a resist mask suitable for an evaporation method and a lift-off method such as a double layer resist of undercut profile is used, for example. The formation regions R1 and R2 are coated with this resist, and openings are formed for exposing portions of the surface of the hole channel layer 22b of the compound semiconductor multilayer structure 22 in the formation region R2. The portions correspond to the electrode forming positions of the source electrode 25 and the drain electrode 26. Thus, the resist mask having such openings is formed.

With using this resist mask, an electrode material such as Ni for example, is deposited on the resist mask having the openings by an evaporation method, for example. Ni is deposited to a thickness of about 100 nm. The resist mask and Ni deposited thereon are removed by a lift-off method.

Subsequently, the Si substrate 1 is subjected to a heat treatment at 400-1000° C., or more specifically about 600° C. for example, in nitrogen atmosphere, for example, to form ohmic contacts between Ta/Al remained and the electron supply layer 21d in the formation region R1, and between Ni remained and the hole channel layer 22b in the formation region R2. In some cases, no heat treatment may be performed when the ohmic contacts between Ta/Al and the electron supply layer 21d and the ohmic contacts between Ni and the hole channel layer 22b are formed without any heat treatment. Thus, the source electrode 23 and the drain electrode 24 are formed in the formation region R1, and the source electrode 25 and the drain electrode 26 are formed in the formation region R2. Here, the source electrode 25 corresponds to an electrode of power supply voltage. G_{DD} of the gate driver circuit, and the drain electrode 26 corresponds to an electrode that is electrically connected to the gate electrode of the AlGaN/GaN HEMT.

Subsequently, as illustrated by FIG. 7B, a gate insulation film 27 is formed in the formation region R2. More specifically, an insulation material such as Al₂O₃, for example, is deposited on the compound semiconductor multilayer structure 22 in the formation region R2. Al₂O₃ is formed by an atomic layer deposition (ALD) method, for example, in which TMA gas and O₃ are alternately supplied. In the present embodiment, Al₂O₃ may be deposited to a thickness of 2-200 nm, or more specifically 10 nm, for example, in this case. Thus, the insulation film 27 is formed on the hole channel layer 22b so as to cover inner walls of the electrode recess 22ba.

Instead of the ALD method, Al₂O₃ may be deposited by a plasma CVD method, a sputtering method, or the like. Furthermore, instead of depositing Al₂O₃, nitride or oxynitride of Al may be deposited. Alternatively, the gate insulation film may be formed by depositing oxide, nitride, or oxynitride of one element selected from the group consisting of Si, Hf, Zr, Ti, Ta, and W, or by depositing multiple layers of suitably selected members thereof.

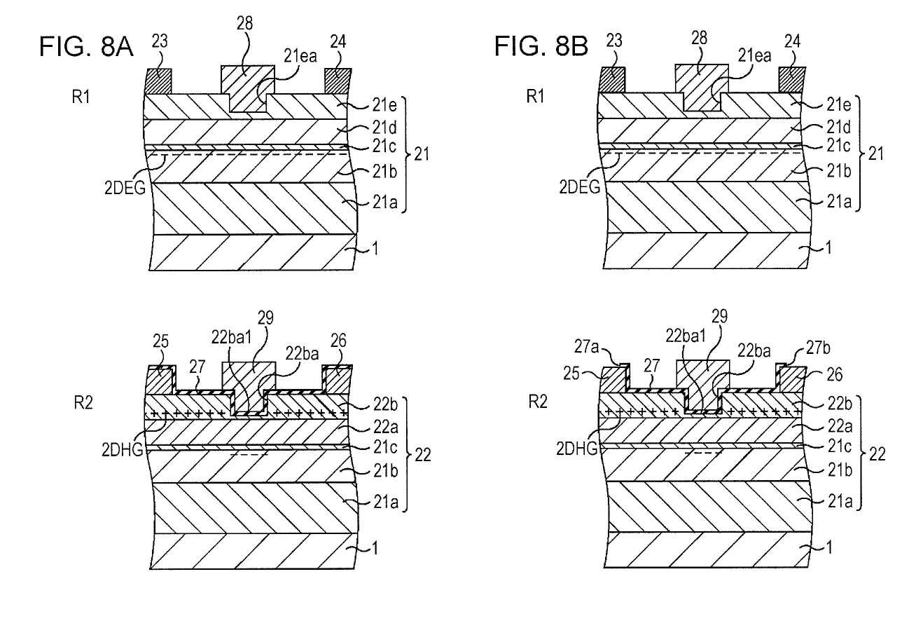

Subsequently, as illustrated in FIG. 8A, a gate electrode 28 is formed in the formation region R1, and a gate electrode 29 is formed in the formation region R2.

First, the formation of the gate electrode 28 is described. A resist mask is formed on the compound semiconductor multilayer structure 21 for forming the gate electrode 28. Namely, the formation regions R1 and R2 are coated with resist, and an opening is formed for exposing the electrode recess 21ea of the cap layer 21e in the formation region R1. Thus, the resist mask having such an opening is formed. With using this resist mask, electrode materials such as Ni/Au, for example, are deposited on the resist mask having the foregoing opening by an evaporation method, for example. Ni has a thickness of about 30 nm, and Au has a thickness of about 400 nm. The resist mask and Ni/Au deposited thereon are removed by a lift-off method. Thus, the gate electrode 28 is formed in such a way that its lower portion is buried into the electrode recess 21ea while its upper portion protrudes upward from the electrode recess 21ea.

Next, the formation of the gate electrode 29 is described. A resist mask is formed on the gate insulation film 27 for forming the gate electrode 29. Namely, the formation regions R1 and R2 are coated with resist, and an opening is formed to expose a portion at the surface of the gate insulation film 27 in the formation region 2. The portion is aligned with the electrode recess 22ba positioned below. Thus, the resist mask having such an opening is formed.

With using this resist mask, an electrode material such as Ti, for example, is deposited on the resist mask having the foregoing opening by an evaporation method, for example. Ti is deposited to a thickness of about 100 nm. The resist mask and Ti deposited thereon are removed by a lift-off method. Thus, the gate electrode 29 is formed in such a way that its lower portion is buried into the electrode recess 22ba of the hole channel layer 22b with having the gate insulation film 27 in between while its upper portion protrudes upward from the electrode recess 22ba with having the gate insulation film 27 in between. The gate electrode 29 serves as a gate electrode in the gate driver circuits high side.

Subsequently, as illustrated in FIG. 8B, in the formation region R2, openings 27a and 27b are formed in the insulation film 27 at positions above the source electrode 25 and the drain electrode 26. More specifically, the gate insulation film 27 is processed by photolithography and dry etching, and portions of the gate insulation film 27 at the positions above the source electrode 25 and the drain electrode 26 are removed. Thus, the openings 27a and 27b, which exposes surfaces of the source electrode 25 and the drain electrode 26, are formed in the gate insulation film 27.

Subsequently, in the formation region R1, a plurality of process steps are performed to complete the AlGaN/GaN HEMT of Schottky type according to the present embodiment. The process steps may include steps such as electrical connections of the source electrode 23, the drain electrode 24, and the gate electrode 28; pad formation of the source electrode 23 and the drain electrode 24; etc. On the other hand, in the formation region R2, a plurality of process steps are performed to complete the p-type GaN transistor of the gate driver circuit's high side. The process steps may include steps such as electrical connections of the source electrode 25, the drain electrode 26, and the gate electrode 29; pad formation of the source electrode 25, the drain electrode 26, and the gate electrode 29, etc.

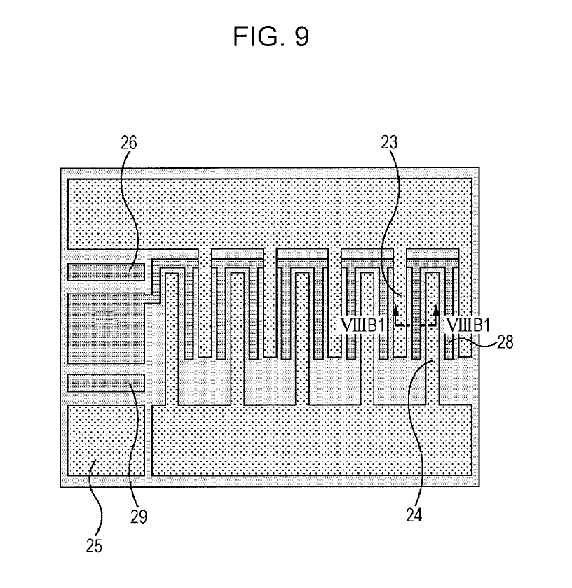

FIG. 9 illustrates a plane view of the AlGaN/GaN HEMT including a gate driver circuit according to the present embodiment. The upper section of FIG. 8B corresponds to a cross-section along a dashed line VIIIBI-VIIIBI of FIG. 9, and the lower section of FIG. 8B corresponds to a cross-section along a dashed line of FIG. 9. In the AlGaN/GaN HEMT, the source electrode 23 and the drain electrode 24 are formed in comb teeth like shapes and arranged in parallel to each other. The gate electrode 28 is also formed in a comb teeth like shape, and is arranged in between and in parallel to the source electrode 23 and the drain electrode 24. The gate driver circuit's high side is configured to include the gate electrode 29, the source electrode 25 that corresponds to the electrode of power supply voltage G_{DD}, and the drain electrode 26 that corresponds to the electrode electrically connected with the gate electrode 28. The low side is configured as a n-type AlGaN/GaN HEMT, for example.

In the present embodiment, the AlGaN/GaN HEMT of Schottky type is formed in the formation region R1 as an example case. Alternatively, as is the case in the formation region R2, a MIS type AlGaN/GaN HEMT may be formed in the formation region R1. Furthermore, both the AlGaN/GaN HEMT in the formation region R1 and the p-type transistor in the formation region R2 may be formed as Schottky type.

Experiments are performed to measure characteristics of the AlGaN/GaN HEMT including a gate driver circuit according to the present embodiment. Results of the experiments are described below. An AlGaN/GaN HEMT including a gate driver circuit, in which n-type AlGaN/GaN HEMTs are employed in both the high side and the low side, is used as an comparative example to the present embodiment.

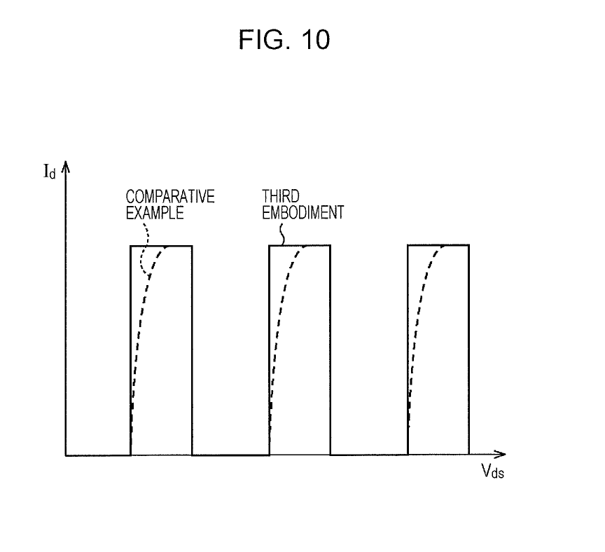

In an experiment 1, a relation between a drain-source voltage Vds and a drain current Id is measured as one of gate driver characteristics. FIG. 10 illustrates a result of the experiment. In the comparative example, rising edges in a waveform of the drain current Id are blunt. On the other hand, in the present embodiment, a rectangle waveform with sharp rising edges is obtained for the drain current Id.

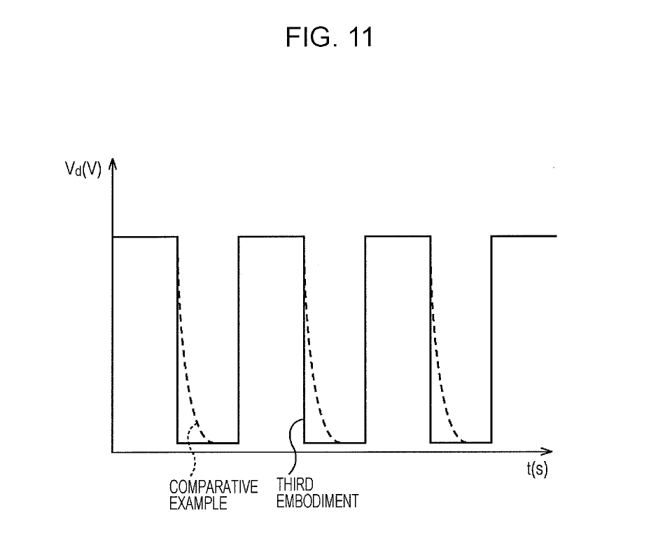

In an experiment 2, a relation between a drain voltage Vd and time is measured as another one of the gate driver characteristics. FIG. 11 illustrates a result of the experiment. A waveform in the comparative example has blunt falling edges while a rectangular waveform is obtained in the present embodiment.

As described above, the present embodiment may be able to achieve a highly reliable p-type GaN transistor of comparably simpler structure, which achieves a rapid current rise at turning ON; enables monolithic integration of an inverter with a n-type AlGaN/GaN HEMT without going through complex processing; and enables to set the power supply and the gate electrode in the gate driver circuit's high side to the same voltage.

The AlGaN/GaN HEMT including a gate driver circuit according to the present embodiment is applicable to a so-called discrete package. On this discrete package, the AlGaN/GaN HEMT including a gate driver circuit according to the present embodiment is mounted. Below, the discrete package of a chip (hereinafter, referred to as HEMT chip) of the AlGaN/GaN HEMT including a gate driver circuit according to the present embodiment is described as an example.

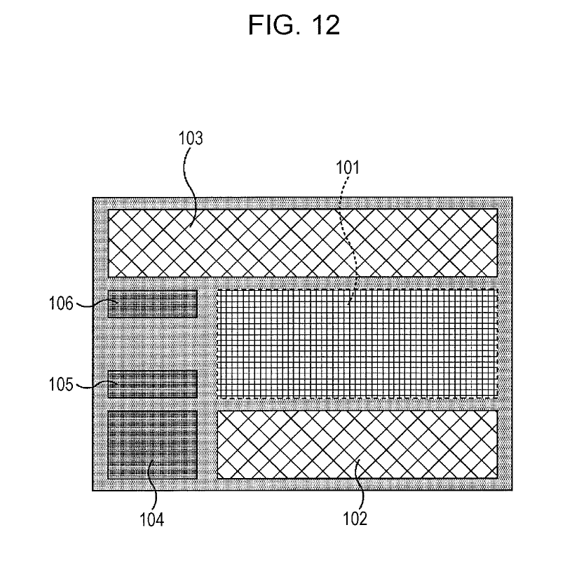

FIG. 12 illustrates a schematic structure of the HEMT chip (corresponds to FIG. 4). The HEMT chip 100 is provided with, in its surface, a transistor region 101, a drain pad 102 connected to a drain electrode, and a source pad 103 connected to a source electrode, for the forgoing AlGaN/GaN HEMT. For the gate driver circuit, the HEMT chip 100 is provided with a G_{DD} pad 104 connected to a drain electrode that corresponds to the power supply voltage G_{DD}, a G1 pad 105 connected to a high side gate electrode, and a G2 pad 106 connected to a low side gate electrode.

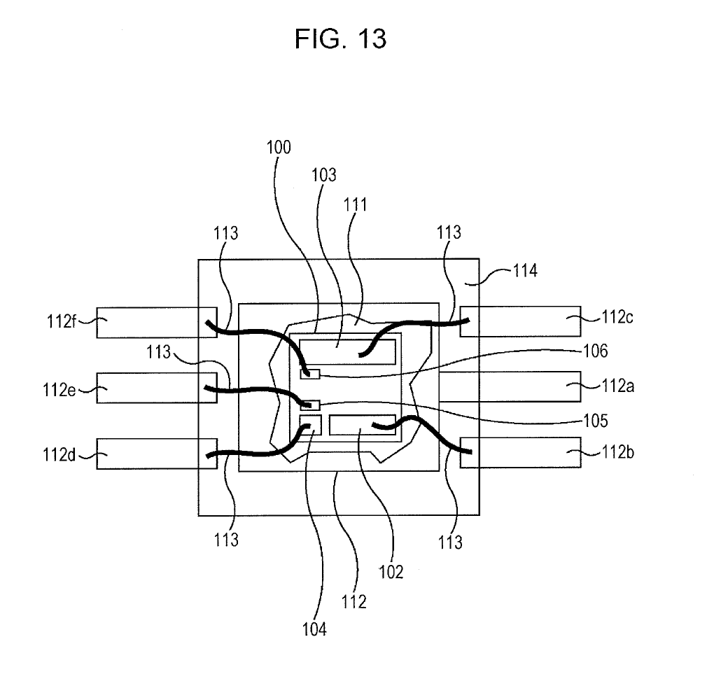

FIG. 13 is a schematic plane view illustrating the discrete package. In fabrication of the discrete package, first, the HEMT chip 100 is fixed on a lead-frame 112 using a die attaching agent 111 such as solder, etc. The lead-frame 112 is integrally formed with a casing lead 112a. The lead frame 112 is formed and arranged separately from a drain lead 112b, a source lead 112c, a G_{DD} lead 112d, a G1 lead 112e, and a G2 lead 112f.

Subsequently, the drain pad 102 and the drain lead 112b, the source pad 103 and the source lead 112c, the G_{DD} pad 104 and the G_{DD} lead 112d, the G1 pad 105 and the G1 lead 112e, the G2 pad 106 and the G2 lead 112f are electrically connected to each other by bonding using Al wires 113. Subsequently, the HEMT chip 100 is resin sealed with molding resin 114 by a transfer molding method, and separated from the lead frame 112. Thus, the discrete package is formed.

### Fourth Embodiment

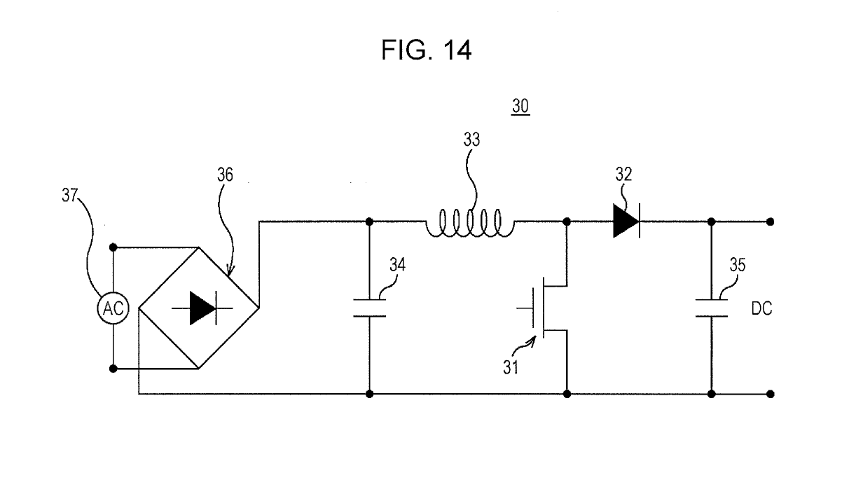

The present embodiment discloses a power factor correction (PFC) circuit that includes an AlGaN/GaN HEMT including a gate driver circuit according to the third embodiment. FIG. 14 is a connection wiring diagram illustrating the PFC circuit according to the fourth embodiment.

The PFC circuit 30 is configured to include a switching element (transistor) 31, a diode 32, a choke coil 33, capacitors 34, 35, a diode bridge 36, and an AC power supply 37. As the switching element 31, the AlGaN/GaN HEMT including a gate driver circuit according to the third embodiment is employed.

In the PFC circuit 30, a drain electrode of the switching element 31 is connected to an anode terminal of the diode 32 and one terminal of the choke coil 33. A source electrode of the switching element 31 is connected to one terminal of the capacitor 34 and one terminal of the capacitor 35. The other terminal of the capacitor 34 is connected to the other terminal of the choke coil 33. The other terminal of the capacitor 35 is connected to a cathode terminal of the diode 32. In between two terminals of the capacitor 34, the AC power supply 37 is connected via the diode bridge 36. In between two terminals of the capacitor 35, a DC power supply is connected. A PFC controller which is not illustrated in the figure is connected to the switching element 31.

In the present embodiment, the AlGaN/GaN HEMT including a gate driver circuit according to the third embodiment is employed in the PFC circuit 30. Thus, a highly reliable PFC circuit 30 is realized.

### Fifth Embodiment

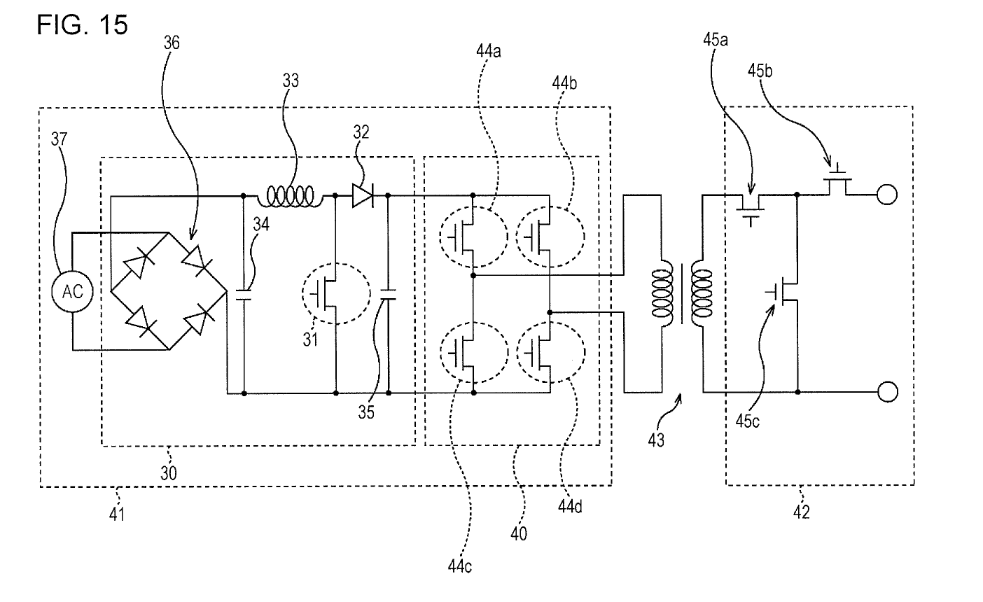

The present embodiment discloses a power supply apparatus that includes an AlGaN/GaN HEMT including a gate driver circuit according to the third embodiment. FIG. 15 is a connection wiring diagram illustrating a schematic structure of the power supply apparatus according to the fifth embodiment.

The power supply apparatus according to the present embodiment is configured to include a high-voltage primary side circuit 41, a low-voltage secondary side circuit 42, and a transformer 43 that is provided between the primary side circuit 41 and the secondary side circuit 42. The primary side circuit 41 includes the PFC circuit 30 according to the fourth embodiment and an inverter circuit connected in between two terminals of the capacitor 35 of the PFC circuit 30. The inverter circuit may be a full-bridge inverter circuit 40, for example. The full-bridge inverter circuit 40 is configured to include a plurality of switching elements 44a, 44b, 44c, 44d (four in this case). The secondary side circuit 42 is configured to include a plurality of switching elements 45a, 45b, 45c (three in this case).

In the present embodiment, the PFC circuit included in the primary side circuit 41 is the PFC circuit 30 according to the fourth embodiment, and the switching elements 44a, 44b, 44c, 44d of the full-bridge inverter circuit 40 are each the AlGaN/GaN HEMT including a gate driver circuit according to the third embodiment. On the other hand, the switching elements 45a, 45b, 45c of the secondary side circuit 42 are typical silicon MIS FETs.

In the present embodiment, the PFC circuit 30 according to the fourth embodiment and the AlGaN/GaN HEMT including a gate driver circuit according to the third embodiment are employed in the primary side circuit 41 that is a high voltage circuit. Thus, a highly reliable high-power power supply apparatus is realized.

### Sixth Embodiment

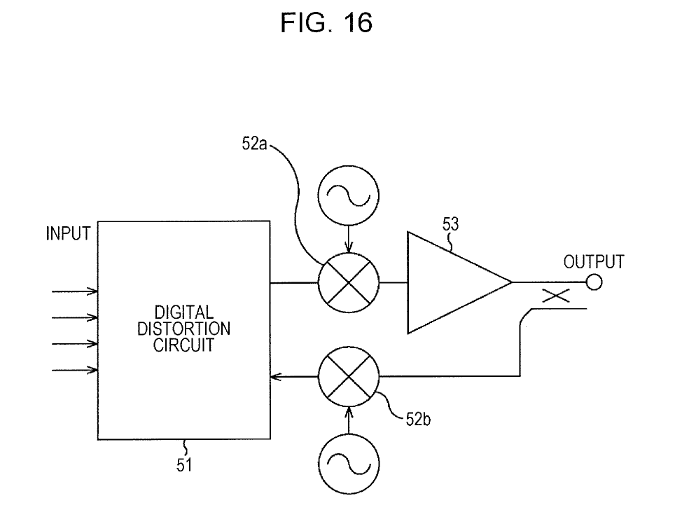

The present embodiment discloses a high frequency amplifier that includes an AlGaN/GaN HEMT including a gate driver circuit according to the third embodiment, FIG. 16 is a connection wiring diagram illustrating a schematic structure of the high frequency amplifier according to the sixth embodiment.

The high frequency amplifier according to the present embodiment is configured to include a digital predistortion circuit 51, mixers 52a, 52b, and a power amplifier 53. The digital predistortion circuit 51 compensates nonlinear distortions of an input signal. The mixer 52a mixes an AC signal and the input signal which nonlinear distortions are compensated. The power amplifier 53 amplifies the input signal that is mixed with the AC signal, and includes the AlGaN/GaN HEMT including a gate driver circuit according to the third embodiment. In FIG. 16, the high frequency amplifier is configured such that, by turning a switch, for example, an output side signal and an AC signal are allowed to be mixed by the mixer 52b and sent to the digital predistortion circuit 51.

In the present embodiment, the AlGaN/GaN HEMT including a gate driver circuit according to the third embodiment is employed in the high frequency amplifier. Thus, a highly-reliable high-withstand-voltage high frequency amplifier is realized.

### Other Embodiments

In the first embodiment, the p-type GaN transistor is described as an example of the compound semiconductor device. In the third embodiment, the AlGaN/GaN HEMT including a gate driver circuit is described as an example of the compound semiconductor device. In addition to the p-type GaN transistor and the AlGaN/GaN HEMT including a gate driver circuit, the following devices may be employed as the compound semiconductor devices.

### Other Device Example 1

In the present example, a transistor with InAlN is disclosed as the p-type GaN transistor, and an InAlN/GaN HEMT is disclosed as the HEM InAlN and GaN are compound semiconductors which lattice constants may be made closer by arranging their compositions. In the present example, the hole supply layer of the first embodiment is formed of n-InAlN, and the hole channel layer of the first embodiment is formed with p-GaN. Furthermore, in the present example, almost no piezoelectric polarization is induced. Therefore, the two dimensional electron gas is produced mostly due to the spontaneous polarization of p-GaN.

In the foregoing third embodiment, the InAlN/GaN HEMT may be formed by growing the electron channel layer with i-GaN, the intermediate layer with AlN, the electron supply layer with n-InAlN, and the cap layer with n-GaN. Furthermore, in the present example, almost no piezoelectric polarization is produced. Therefore, the two dimensional electron gas is produced mostly due to the spontaneous polarization of InAIN. The p-type GaN transistor may be formed by growing the electron channel layer with i-GaN, the intermediate layer with AlN, the hole supply layer with n-InAlN, and the hole channel layer with p-GaN. Furthermore, in the present example, almost no piezoelectric polarization is produced. Therefore, the two dimensional electron gas is produced mostly due to the spontaneous polarization of p-GaN.

The present example may be able to achieve a highly reliable p-type GaN transistor with InAlN, which achieves a rapid current rise at turning ON; and enables monolithic integration of an inverter with a n-type HEMT without going through complex processing, as is the case with the foregoing p-type GaN transistors.

### Other Device Example 2

In the present example, a transistor with InAlGaN is disclosed as the p-type GaN transistor, and an InAlGaN/GaN HEMT is disclosed as the HEMT. InAlGaN and GaN are compound semiconductors which lattice constants may be made closer by arranging their compositions. In the present example, the hole supply layer of the first embodiment is formed as n-InAlGaN, and the hole channel layer of the first embodiment is formed as p-GaN.

In the foregoing third embodiment, the InAlGaN/GaN HEMT may be formed by growing the electron channel layer with i-GaN, the intermediate layer with i-InAlGaN, the electron supply layer with n-InAlGaN, and the cap layer with n-GaN. The p-type GaN transistor may be formed by growing the electron channel layer with i-GaN, the intermediate layer with i-InAlGaN, the hole supply layer with n-InAlGaN, and the hole channel layer with p-GaN.

The present example may be able to achieve a highly reliable p-type GaN transistor with InAlGaN, which achieves a rapid current rise at turning ON; and enables monolithic integration of an inverter with a n-type HEMT without going through complex processing, as is the case with the foregoing p-type GaN transistors.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a first element structure that includes
a charge supply layer of first polarity;
a charge channel layer of second polarity, the charge channel layer being formed above the charge supply layer and including a recess portion; and
a first electrode formed in the recess portion above the charge channel layer.

2. The semiconductor device according to claim 1,
wherein the recess portion is a non-penetrating opening that does not go through the charge channel layer.

3. The semiconductor device according to claim 1,
wherein the first polarity is negative polarity.

4. The semiconductor device according to claim 3, further comprising:
a second element structure,
wherein the first element structure further includes an electron channel layer of the first polarity formed below the charge channel layer, and
wherein the second element structure includes:
the electron channel layer;
an electron supply layer that is a same layer as the charge supply layer and formed above the electron channel layer; and
a second electrode formed above the electron supply layer.

5. A method of manufacturing a semiconductor device including a first element structure, the method comprising, for manufacturing the first element structure:
forming a charge supply layer of first polarity;
forming a charge channel layer of second polarity above the charge supply layer;
forming a recess portion in the charge channel layer; and
forming a first electrode in the recess portion above the charge channel layer.

6. The method of manufacturing a semiconductor device according to claim 5,
wherein the recess portion is formed as a non-penetrating opening that does not go through the charge channel layer.

7. The method of manufacturing a semiconductor device according to claim 5,
wherein the first polarity is the negative polarity.

8. The method of manufacturing a semiconductor device according to claim 5,
the method being a method of manufacturing a semiconductor device including a second element structure in addition to the first element structure, the method further comprising:
forming an electron channel layer of the second element structure;
forming the charge supply layer of the first element structure together with an electron supply layer of the second element structure, the electron supply layer of the second element structure being formed above the electron channel layer of the second element structure; and
forming a second electrode of the second element structure above the electron supply layer of the second element structure.

9. A battery charger for charging a battery, comprising a semiconductor device,
wherein the semiconductor device includes:
a charge supply layer of first polarity;
a charge channel layer of second polarity, the charge channel layer being formed above the charge supply layer and including a recess portion; and
a first electrode formed in the recess portion above the charge channel layer.

10. A power supply apparatus including a high voltage circuit, a low voltage circuit, and a transformer in between the high voltage circuit and the low voltage circuit,
wherein the high voltage circuit includes a transistor, the transistor including a first element structure and a second element structure,
the first element structure including:
an electron channel layer of first polarity;
a charge supply layer of the first polarity formed above the electron channel layer;
a charge channel layer of second polarity, the charge channel layer being formed above the charge supply layer and including a recess portion; and
a first electrode formed in the recess portion above the charge channel layer,
the second element structure including:
the electron channel layer;
an electron supply layer that is a same layer as the charge supply layer and formed above the electron channel layer; and
a second electrode formed above the electron supply layer.
